(19) United States
(12) Patent Application Publication
(10) Pub. No.: US 2011/0273057 A1
(43) Pub. Date: Nov. 10, 2011

(54) DEVICE AND METHOD FOR CONTROLLING A RESONANT ULTRASOUND PIEZOELECTRIC INJECTOR

(75) Inventor: Clement Nouvel, Clamart (FR)

(73) Assignee: RENAULT s.a.s, Boulogne-Billancourt (FR)

(21) Appl. No.: 13/124,335

(22) PCT Filed: Oct. 13, 2009
(86) PCT No.: PCT/FR2009/051944

§ 371 Date: Jul. 27, 2011

(30) Foreign Application Priority Data
Oct. 14, 2008 (FR) 0856939

(51) Int. Cl. H01L 41/09

(52) U.S. Cl. 310/317

(57) ABSTRACT

A device for controlling a resonant ultrasound piezoelectric stage, including: a first stage of increasing a DC voltage to an intermediate DC voltage, a second modulation stage including an inductor connected to the intermediate DC voltage and a first switching transistor for selectively controlling a phase of charging the inductor and a phase of transferring the energy stored in the inductor in response to a first stream of command pulses, to generate an excitation voltage of the piezoelectric stage. The second stage includes a second switching transistor connected in series between the drain of the first transistor and a terminal of the inductor, suitable for limiting energy stored in the inductor during the charging phase in response to a second stream of command pulses, so as to reduce an amplitude of the excitation voltage.

The present invention relates to the field of electronic injection in an internal combustion engine of a motor vehicle. The invention relates more particularly to a device and a method for controlling a resonant ultrasound piezoelectric stage fuel injector.

A known structure of a control device of this type is shown schematically in FIG. 1.

Such a device is designed to control at least one resonant ultrasound piezoelectric stage 1 of an injector controlled electronically from a control computer 10 and from a direct current voltage source V_{BATT}, the battery of the vehicle for example. The control device comprises:
a first stage 2 of stepping up the direct current voltage V_{BATT} in order to generate an intermediate direct current voltage Vᵢₙₜₑᵣ (a few hundreds of volts, for example 250 V),
a second stage 3 of modulating the intermediate direct current voltage Vᵢₙₜₑᵣ supplied by the intermediate direct current voltage Vᵢₙₜₑᵣ and suitable for generating an alternating excitation voltage V_{E} of the resonant ultrasound piezoelectric stage 1.

Certain situations make it necessary to be able to finely vary the quantity of injected fuel during injection, for example in order to compensate for variations in pressure in the combustion chamber into which the fuel is injected or else in order to adapt to particular flow-rate profiles.

However, in order to make it possible to influence with great flexibility the injected fuel flow-rate profile during injection, it is essential to be able to vary the amplitude of the excitation signal of the piezoelectric stage 1 of the injector (i.e. the amplitude of the signal V_{E} at the output of the modulation stage 3) both flexibly and rapidly.

Accordingly, it could be possible to envisage rapidly varying the intermediate voltage Vᵢₙₜₑᵣ supplied at the output of the voltage step-up stage 2. Therefore, the amplitude of the envelope of the voltage V_{E} at the output of the modulation stage could also change rapidly as a consequence.

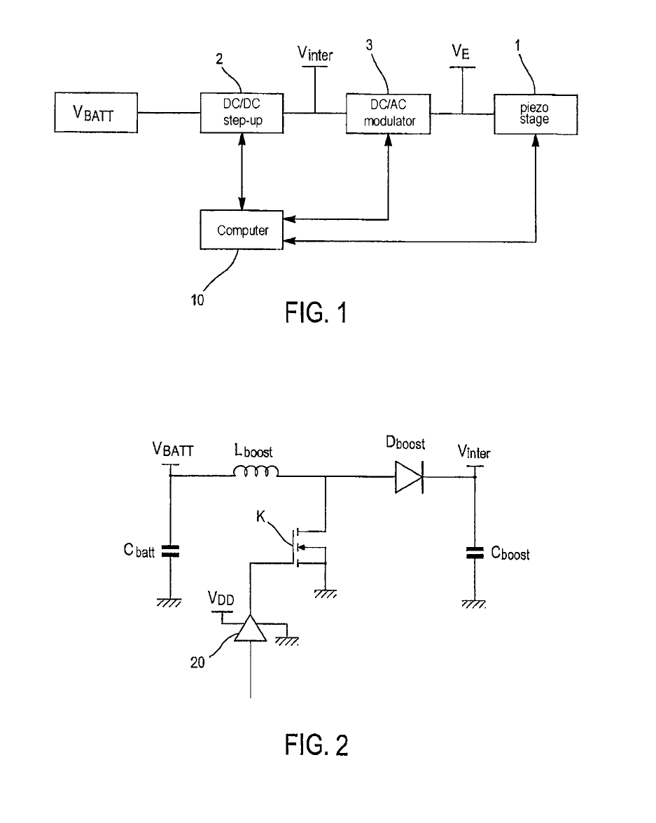

FIG. 2 illustrates a voltage converter circuit of the “boost” type, conventionally used to produce the voltage step-up stage 2 from the direct current voltage source V_{BATT}, for example the battery with a capacity C_{batt}. This circuit consists of an inductor L_{boost}, of an MOSFET transistor K, which serves as a switch controlled by a control module 20, of a diode D_{boost}, and of a storage capacitor C_{boost}. The control module delivers a signal in the form of a stream of high frequency pulses so that the transistor K is periodically made conductive. When the transistor K is closed, the inductor L_{boost} is charged with the voltage V_{BATT} at its terminals. When the transistor K is open, the diode D_{boost} conducts and the energy stored in the inductor gives rise to a current that will charge the capacitor C_{boost}.

The storage capacitor C_{boost} is charged in this manner until the desired value of Vᵢₙₜₑᵣ is achieved at its terminals.

This voltage step-up circuit of the “boost” type does not however make it possible to obtain rapid amplitude variations in the intermediate voltage Vᵢₙₜₑᵣ that is generated. It should be greatly oversized in order to be able to obtain the desired effect at the output of the modulation stage 3, namely rapid variations in the excitation voltage V_{E} propagated at the output of this stage. Such an oversizing would however induce the selection of a very bulky and very expensive transistor and problems of poor efficiency and hence of heating up the voltage step-up stage 2.

Therefore, one object of the invention is to propose a solution making it possible to very rapidly vary the amplitude of the envelope of the excitation signal of the resonant ultrasound piezoelectric stage of the injector at the output of the modulation stage while maintaining control electronics of reasonable size, ensuring an acceptable volume/weight/cost compromise in the context of motor vehicle engine control.

With this object in view, the subject of the invention is a device for controlling at least one resonant ultrasound piezoelectric stage of an injector that is controlled electronically from a control computer and from a direct current voltage source, comprising:
a first stage of stepping up the direct current voltage in order to generate an intermediate direct current voltage, and
a second stage of modulating the intermediate direct current voltage, comprising an inductor connected to the intermediate direct current voltage and a first switching transistor suitable for selectively controlling a phase of charging the inductor and a phase of transferring the energy stored in the inductor in response to a first stream of control pulses, in order to generate an excitation voltage of the resonant ultrasound piezoelectric stage.

The invention is more particularly characterized in that the second stage comprises a second switching transistor connected in series between the drain of the first switching transistor and a terminal of the inductor, suitable for limiting the energy stored in the inductor during the charging phase in response to a second stream of control pulses, so as to reduce the amplitude of the excitation voltage.

Advantageously, the drain of the first switching transistor is connected to the resonant ultrasound piezoelectric stage by means of a capacitor.

As a variant, the drain of the first switching transistor may furthermore be connected to the resonant ultrasound piezoelectric stage by means of a transformer.

According to this variant, the primary winding of the transformer is connected via one terminal to the drain of the first switching transistor and via another terminal to ground, the primary winding being connected in parallel with the capacitor.

According to another variant, the drain of the second switching transistor is connected to the resonant ultrasound piezoelectric stage by means of a transformer.

According to this other variant, the primary winding of the transformer is connected via one terminal to the intermediate direct current voltage and via another terminal to the drain of the second switching transistor, a capacitor being connected between the intermediate direct current voltage and the drain of the first switching transistor.

Preferably, the second stream of control pulses is a PWM signal suitable for controlling the second switching transistor into an open state for at least a portion of the charging phase during which the first switching transistor is controlled into a closed state.

Advantageously, the first voltage step-up stage comprises a voltage converter of the BOOST type.

The invention also relates to a method for controlling at least one resonant ultrasound piezoelectric stage of an injector controlled electronically from a control computer and from a direct current voltage source, comprising the steps of:
amplification of the direct current voltage in order to generate an intermediate direct current voltage;
generation of an excitation voltage of the resonant ultrasound piezoelectric stage from the intermediate direct current voltage, said step consisting in controlling at a control frequency a first switching transistor into a closed state in order to control a charging phase of an inductor connected to the intermediate direct current voltage and into an open state in order to control a phase for transferring the energy stored in the inductor to the resonant ultrasound piezoelectric stage,
   said method being characterized in that it comprises a step of limiting the energy stored in the inductor for the charging phase in order to reduce the amplitude of the excitation signal, consisting in controlling a second switching switch placed in series between the drain of the first switching transistor and the inductor into an open state for at least a portion of the charging phase.

Advantageously, the reduction in the amplitude of the excitation voltage of the resonant ultrasound piezoelectric stage depends on the opening time of the second switching transistor during each charging phase.

Other features and advantages of the present invention will appear more clearly on reading the following description given as an illustrative and nonlimiting example and made with reference to the appended figures in which:

FIG. 1 represents a simplified electronic diagram of a known control device of a resonant ultrasound piezoelectric stage of a fuel injector of an internal combustion engine and has already been described;

FIG. 2 represents an electronic diagram of a method for producing a first stage of the known control device of FIG. 1, forming a voltage step-up stage of the “boost” type, and has already been described;

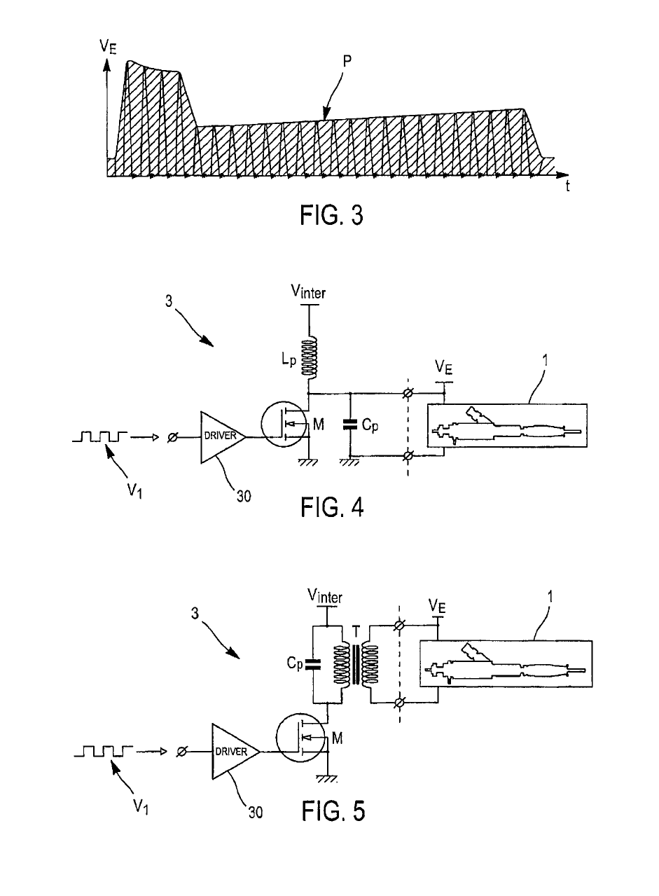

FIG. 3 represents a timing chart illustrating a variable amplitude envelope profile with a large dynamic range of the control voltage obtained at the output of a second voltage modulation stage of the control device according to the invention;

FIG. 4 represents an electronic diagram of a method for producing the second voltage modulation stage of the known control device, connected to the piezoelectric stage of the injector;

FIG. 5 represents a variant embodiment of FIG. 4;

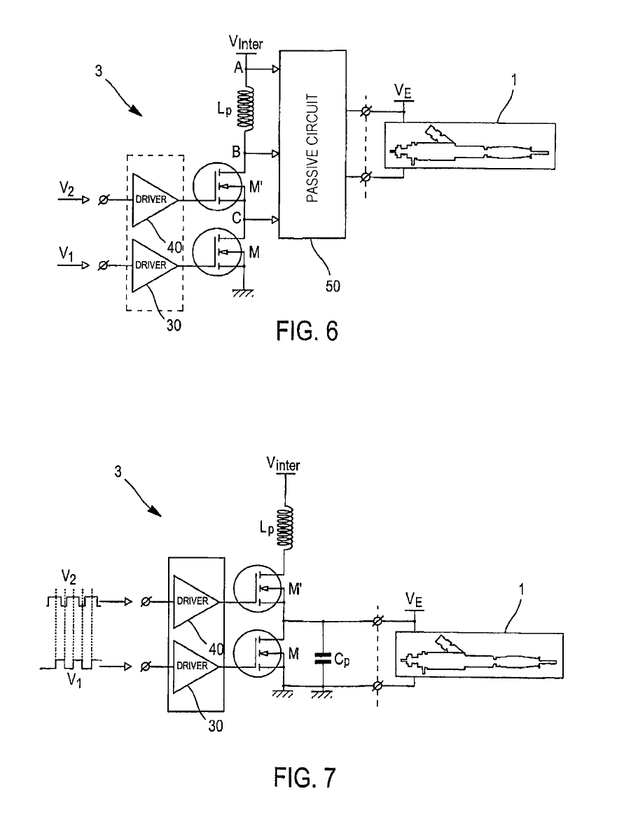

FIG. 6 represents an electronic diagram of the voltage modulation stage of an injector control device according to the invention, based on a structure of the half-bridge type with serial inductor;

FIGS. 7 to 9 represent variants of the circuit of FIG. 6 with several possible configurations of passive circuits downstream of the half-bridge type structure;

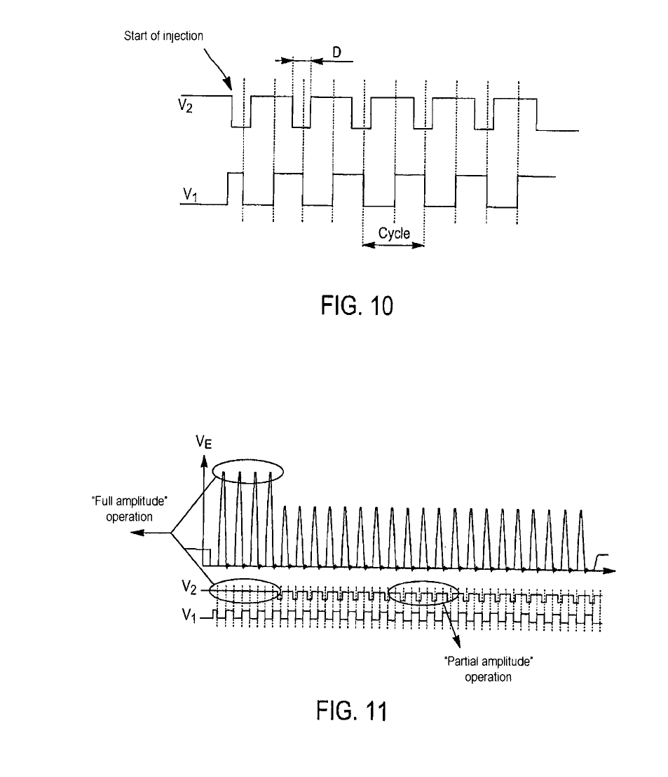

FIG. 10 represents timing charts of the respective control signals of the transistors comprising the structure of half-bridge type on which rests the voltage modulation stage of the injector control device of the invention;

FIG. 11 represents an example of modulation of the excitation signal of the injector according to the principles of the invention.

The invention is based on the control device with the voltage step-up and modulation stages, already described with reference to FIG. 1.

The invention proposes to modify the modulation stage of the control device described above so as to be able to vary the amplitude of the excitation voltage supplied at the output of this stage (and therefore at the input of the injector concerned) with a large dynamic range. This principle of varying the amplitude of the excitation voltage envelope of the injector with a large dynamic range is described with reference to FIG. 3 which shows a profile P of an envelope of excitation voltage V_{E} suitable to allow particularly flexible injection controls.

It therefore involves being able to modulate the amplitude of the excitation voltage peaks of the injector in addition to the modulation carried out by the modulation stage, which for its part consists in producing the voltage peaks themselves, preferably at the resonance frequency of the injector.

In order to produce this type of voltage envelope signal as shown in FIG. 3, the modulation stage 3 of the control device according to the invention is based on a topology that is also known, as described in FIG. 4.

The voltage modulation stage 3 is therefore used in the form of a pulse voltage generator capable of delivering the excitation voltage V_{E} of the ultrasound piezoelectric stage 1 of the injector connected at the output, in the form of a stream of voltage pulses in response to a stream of control pulses V₁ at an appropriate frequency received on a control electrode of a switching transistor M, for example a transistor of the MOSFET type, via a driver stage 30.

More precisely, this pulse voltage generator comprises an inductance coil Lₚ connected to the intermediate direct current voltage Vᵢₙₜₑᵣ (the output of the voltage step-up stage 2) and controlled by the transistor M, and a capacitor in parallel with the coil, of capacitor Cₚ, to the terminals of which the resonant ultrasound piezoelectric stage 1 is connected.

The resonant ultrasound piezoelectric stage injector can be modeled by a serial resonator comprising a resistor in series with an inductor and a capacitor. The combination of the pulse tension generator and the serial resonator modeling the charge of the resonant ultrasound piezoelectric injector is normally called by those skilled in the art a “pseudo class E amplifier”.

Therefore, under the effect of the stream of control pulses V₁ applied to the gate of the transistor M, the drain of the latter makes it possible to deliver the stream of pulses of voltage V_{E} capable of exciting the resonant ultrasound piezoelectric stage 1 connected at the output of the modulation stage 3.

As a variant, with reference to FIG. 5, the pulse voltage generator comprises a transformer T and capacitor Cₚ assembly connected in parallel between the intermediate direct current voltage Vᵢₙₜₑᵣ and the drain of the switching transistor M. More precisely, the drain of the switching transistor M is connected to the resonant ultrasound piezoelectric stage 1 via the transformer T, the primary winding of which is connected in parallel to the capacitor Cₚ between the intermediate direct current voltage Vᵢₙₜₑᵣ and the drain of the transistor M and of which the secondary winding is connected to the resonant ultrasound piezoelectric stage 1.

The operating cycle of the class E amplifiers is based on two operating phases repeated constantly at the frequency defined by the control stream, corresponding to the resonance frequency of the charge resonator:
Charge phase: the transistor M is closed; the charge resonator is short-circuited and resonates “on itself” (it loses a little energy in its dissipative elements), while the inductor Lₚ is charged because it is powered by Vᵢₙₜₑᵣ.
Transfer phase: the transistor M is open; the energy stored in the inductor is redirected toward the charge resonator and compensates for the losses of the latter.

The amplification factor of this type of topology (i.e. the ratio between Vᵢₙₜₑᵣ and the peak-to-peak amplitude of the output voltage V_{E}) is structurally of the order of 3 to 4. Specifically, it is not possible to control the quantity of energy stored in the inductor, then redirected toward the resonator charged on each cycle. The amplitude of the excitation voltage V_{E} at the output of the voltage modulation stage is therefore mainly dictated by the value of the output voltage Vᵢₙₜₑᵣ of the voltage step-up stage.

FIG. 6 then describes a new topology for the modulation stage, modifying the operation of “class E” type of the latter so as to be able to very rapidly vary the amplitude of the excitation signal V_{E} supplied at the output of this stage (therefore at the input of the injector concerned). The voltage modulation stage 3 according to the invention is based on a structure of the “half-bridge with serial inductor” type. The half-bridge structure consists of two transistors M and M′ mounted in series between ground and an inductor coil Lₚ supplied by the intermediate direct current voltage Vᵢₙₜₑᵣ.

Therefore, relative to the topology described with reference to FIG. 4 or 5, the pulse voltage generator forming the voltage modulation stage 3 comprises a second switching transistor M′, for example a transistor of the MOSFET type, connected in series between the drain (point C in FIG. 6) of the transistor M (the source of which is connected to ground) and a terminal (point B) of the inductor coil Lₚ, the other terminal of which (point A) is connected to the intermediate direct current voltage source Vᵢₙₜₑᵣ (the output of the voltage step-up stage 2).

The transistors M and M′ are attacked, through drivers 30 and 40, by respective control pulse streams V₁ and V₂ making it possible to control the opening and closure of the transistors M and M′ respectively and of which the features will be explained in detail below.

Moreover, several configurations of passive circuit 50 downstream of the half-bridge structure can be envisaged.

Therefore, FIG. 7 shows in detail a topology with direct amplitude modulation, that is to say for which the resonant ultrasound piezoelectric stage of the injector is directly connected to the transistors M and M′ comprising the half-bridge structure. This topology has the advantage of simplicity and cost. On the other hand, it is not possible to control injectors with an output amplitude greater than the characteristic of the maximum insulation of the transistors used (approximately 1200 V for transistors of the IGBT (“Insulated Gate Bipolar Transistor”) type that can be used in the motor vehicle context.

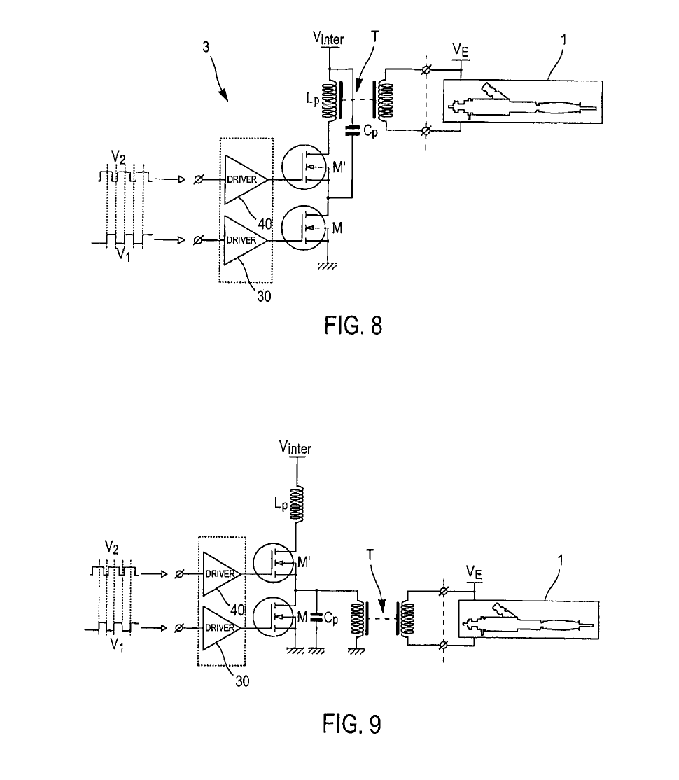

In order to obtain excitation voltages V_{E} of the injector that are greater at the output of the voltage modulation stage 3, it is possible to use topologies with transformer T such as those shown with reference to FIG. 8 and to FIG. 9.

According to FIG. 8, the drain of the second switching transistor M′ is connected to the resonant ultrasound piezoelectric stage 1 via a transformer T. More precisely, the primary winding of the transformer is connected between the intermediate direct current voltage Vᵢₙₜₑᵣ and the drain of the second switching transistor M′, the inductor coil Lₚ then consisting of the primary winding of the transformer T, and the secondary winding is connected to the terminals of the resonant ultrasound piezoelectric stage. A capacitor Cₚ is also connected between the intermediate direct current voltage Vᵢₙₜₑᵣ and the drain of the first switching transistor M.

As a variant, according to FIG. 9, a transformer T and capacitor Cₚ assembly is connected in parallel between the drain of the first switching transistor M and ground. More precisely, the drain of the first switching transistor M is connected to the resonant ultrasound piezoelectric stage 1 via the transformer T, the primary winding of which is connected in parallel to the capacitor Cₚ between the drain of the transistor M and ground, the secondary winding of the transformer being connected to the resonant ultrasound piezoelectric stage 1.

The two variants making it possible to generate amplitudes markedly greater than the insulation characteristic of the transistors used, which also makes it possible to choose a compromise between the ratio of transformation of the transformer and the characteristics of the adapted transistors at a higher efficiency and a lower cost.

Irrespective of the embodiment for the passive circuit downstream of the structure of half-bridge type, the value of the latter lies in the fact that, unlike the “strict” class E topology (FIG. 4 or 5), it is possible to short-circuit the charge resonator modeling the resonant ultrasound piezoelectric stage 1 but without systematically charging the serial inductor Lₚ connected to the intermediate direct current voltage Vᵢₙₜₑᵣ (the output of the voltage step-up stage 2).

Specifically, provided that for a time the second switching transistor M′ is open, it is possible to close the first switching transistor M in order to make the resonant ultrasound piezoelectric stage 1 of the injector resonate, but without charging the inductor Lₚ, which is then separated from ground by virtue of the second switching transistor M′, which makes it possible, in its open state, to disconnect the drain of the first switching connector M from the inductor Lₚ.

Therefore, depending on the opening time of the second switching transistor M′, it is possible to significantly reduce the amplitude of the signal delivered at the output of the stage 3 and therefore to control the amplitude of the envelope of the excitation signal V_{E} applied to the injector concerned.

The present topology based on the structure of half-bridge type consisting of two switching transistors M and M′ controlled respectively by the streams of control pulses V₁ and V₂ therefore makes it possible to modify the operating cycle of class E type of the voltage modulation stage 3 so as to be able to generate an excitation voltage V_{E} of variable amplitude at the output.

In particular, it makes it possible to introduce a new phase, in addition to the charge and transfer phases, into the operating cycle of the class E amplifiers, namely a resonance phase with no charging of the inductor in series with the half-bridge consisting of the transistors M and M′, so as to be able to generate an output of variable amplitude.

For this purpose, as has been seen, the method of controlling the two transistors forming the half-bridge is based mainly on the characteristics of the stream of control pulses V₂ controlling the opening and the closing of the second switching transistor M′.

In the new proposed topology, the stream of control pulses V₁ controlling the opening and the closing of the switching transistor M does not change relative to the control stream employed in the “strict” class E topology described with reference to FIG. 4 or 5.

Such a stream of control pulses V₁ is illustrated in FIG. 10 in the form of a rectangular signal.

Advantageously it has the following features:
duty factor of 50%;
first control pulse approximately twice as short as the subsequent ones.

The reduction in the width of the first pulse specifically makes it possible to minimize the overvoltage of the first peaks, an overvoltage which may be very great (and therefore potentially destructive for the transistor) in the first moments of the injection.

Thus, each operating cycle during an injection control therefore comprises the application of a high state of the stream of control pulses V₁ to the gate of the transistor M (transistor closed), controlling the charging phase in which the inductor Lₚ supplied by Vᵢₙₜₑᵣ is charged and the application of a low state of the stream of control pulses V₁ to the gate of the transistor M (transistor open), controlling the transfer phase in which the energy stored in the inductor is redirected toward the resonant ultrasound piezoelectric stage.

On the other hand, it is essential to use this stream of control pulses V₁ as a phase reference for the second stream of control pulses V₂ of the second switching transistor M′.

The second stream of control pulses V₂ is for example a PWM (“Pulse Width Modulation”) signal, namely a rectangular signal the duty cycle of which can be made to vary, so as to be able to control the opening and closing times of the second switching transistor M′. It is more precisely used to control moments of opening of the transistor M′ during which it is desired to limit the charging of the serial inductor Lₚ, while the first switching transistor M is closed.

This opening configuration of the second switching transistor M′ for at least a portion of the charging phase (that is to say while the first switching transistor M is closed) specifically makes it possible to limit the energy stored in the serial inductor Lₚ on each operating cycle and therefore the total amplitude of the signal supplied at the output of the class E modulation stage 3 in the steady state.

The amplitude of the excitation voltage V_{E} generated at the output of the stage 3 depends essentially on the opening time D of the second switching transistor M′ on each cycle. The longer this opening time, the weaker the energy stored periodically in the serial inductor and the more reduced the amplitude of the excitation voltage V_{E}.

This opening time can be managed by varying the duty cycle of the stream of control pulses V₂.

The following features of the streams of control pulses V₁ and V₂ also has to be taken into account as emerges from FIG. 10:
the first switching transistor M is controlled to the open state (low state of the stream of control pulses V₁) before the beginning of the injection, and
the second switching transistor M′ is controlled to the closed state (high state of the stream of control pulses V₂) before the beginning of the injection.

The half-bridge configuration with the serial inductor of the modulation stage 3 makes it possible to identify two operating cases:
an operation called “full amplitude”, in which the second switching transistor M′ is constantly controlled to the closed state. The operation in this case is identical to the operation of the basic class E modulation stage as described with reference to FIG. 4 or 5, and
an operation called “partial amplitude” in which the second switching transistor M′ is controlled to the open state during the charging phase (that is to say while the first switching transistor M is closed) and controlled to the closed state during the transfer phase (that is to say while the first switching transistor M is open), according to the principles already set out above.

This second operating mode, based on the periodic opening of the second switching transistor M′, therefore makes it possible to control the amplitude of the envelope of the signal V_{E} at the output of the stage 3, throughout the duration of the injection.

It is therefore possible to carry out injections with a modulated control envelope. Such a modulation of the envelope is illustrated in FIG. 11. At the beginning of the injection control, the maximum amplitude of the voltage V_{E} is obtained by constantly controlling the transistor M′ to the closed state. Then, during a second portion of the injection control, the application of the stream of control pulses V₂ in the form of a PWM signal on the gate of the switching transistor M′ makes it possible to limit the value of the amplitude of the voltage V_{E}.

1-10. (canceled)

11. A device for controlling at least one resonance ultrasound piezoelectric stage of an injector that is controlled electronically from a control computer and from a direct current voltage source, comprising:
a first stage of stepping up the direct current voltage to generate an intermediate direct current voltage; and
a second stage of modulating the intermediate direct current voltage, comprising an inductor connected to the intermediate direct current voltage and a first switching transistor configured to control a phase of charging the inductor and a phase of transferring energy stored in the inductor in response to a first stream of control pulses, to generate an excitation voltage of the resonant ultrasound piezoelectric stage,
wherein the second stage comprises a second switching transistor connected in series between a drain of the first switching transistor and a terminal of the inductor, configured to limit the energy stored in the inductor during the charging phase in response to a second stream of control pulses, so as to reduce an amplitude of the excitation voltage.

12. The control device as claimed in claim 11, wherein the drain of the first switching transistor is connected to the resonant ultrasound piezoelectric stage by a capacitor.

13. The control device as claimed in claim 11, wherein the drain of the first switching transistor is connected to the resonant ultrasound piezoelectric stage by a transformer.

14. The control device as claimed in claim 13, wherein a primary winding of the transformer is connected via one terminal to the drain of the first switching transistor and via another terminal to ground, the primary winding being connected in parallel with the capacitor.

15. The control device as claimed in claim 11, wherein a drain of the second switching transistor is connected to the resonant ultrasound piezoelectric stage by a transformer.

16. The device as claimed in claim 15, wherein a primary winding of the transformer is connected via one terminal to the intermediate direct current voltage and via another terminal to the drain of the second switching transistor, a capacitor being connected between the intermediate direct current voltage and the drain of the first switching transistor.

17. The control device as claimed in claim 11, wherein the second stream of control pulses includes a PWM signal configured to control the second switching transistor into an open state for at least a portion of the charging phase during which the first switching transistor is controlled into a closed state.

18. The control device as claimed in claim 11, wherein the first stage comprises a voltage converter of BOOST type.

19. A method for controlling at least one resonant ultrasound piezoelectric stage of an injector controlled electronically from a control computer and from a direct current voltage source, comprising:
amplification of the direct current voltage to generate an intermediate direct current voltage;
generation of an excitation voltage of the resonant ultrasound piezoelectric stage from the intermediate direct current voltage, including controlling at a control frequency a first switching transistor into a closed state to control a charging phase of an inductor connected to the intermediate direct current voltage and into an open state to control a phase for transferring energy stored in the inductor to the resonant ultrasound piezoelectric stage; and
limiting the energy stored in the inductor for the charging phase to reduce an amplitude of the excitation signal, including controlling a second switching switch placed in series between the drain of the first switching transistor and the inductor into an open state for at least a portion of the charging phase.

20. The method as claimed in claim 19, wherein the reduction in the amplitude of the excitation voltage of the resonant ultrasound piezoelectric stage depends on an opening time of the second switching transistor during each charging phase.
